(19) United States
(12) Patent Application Publication
(10) Pub. No.: US 2002/0182850 A1
(43) Pub. Date: Dec. 5, 2002

(54) Interconnect structure manufacturing process

(76) Inventors: Chen-Chiu Hsue, Hsinchu (TW); Shyh-Dar Lee, Hsinchu Hsien (TW); Tzu-Kun Ku, Taipei (TW); Lung Chen, Hsinchu (TW)

Correspondence Address: BIRCH STEWART KOLASCH & BIRCH, PO BOX 747, FALLS CHURCH, VA, 22040-0747, US

(21) Appl. No.: 09/960,982

(22) Filed: Sep. 25, 2001

(30) Foreign Application Priority Data
Jun. 5, 2001 (TW) 90113568

(51) Int. Cl. H01L 21/4763

(52) U.S. Cl. 438/633; 438/637

(57) ABSTRACT

The present invention provides a method to fabricate a interconnect structure. First, an inter-metal dielectric layer is formed on a substrate. Then the inter-metal dielectric layer is etched to form a trench. And a barrier layer is formed to on the trench. Afterwards, a metal layer is formed to fill into the trench over the barrier layer. Then a chemical mechanical polishing (CMP) process is performed to remove the barrier layer and the metal layer on the inter-metal dielectric layer. After the CMP process, a reduction process is performed by providing a reduction gas to remove the metal oxide generated on the metal layer. Finally, a sealing layer is formed to cover the metal layer and the inter-metal dielectric layer.

### BACKGROUND OF THE INVENTION

1. Field of the Invention

The present invention relates in general to a process for manufacturing an interconnect structure. In particular, the present invention relates to a process for manufacturing an interconnect structure which reduces the metal oxide on the metal line in a dual damascene process after chemical mechanical polish processes.

2. Description of the Related Art

In ultra large-scale integrated (ULSI) circuit's manufacturing, semiconductor devices are fabricated on a substrate or a silicon wafer. After the formation of the devices, metal lines for interconnection are defined by using a metallization process. As the integration of integrated circuits increases, manufacturing with high yield and highly reliable metal interconnect lines is hard to achieve. A method of fabricating a metal-damascene structure is to etch trenches for metal interconnect lines and then fill metal material into the trenches. In addition, a chemical mechanical polishing (“CMP” hereinafter) is used to polish the metal material. The method offers a better way to fabricate a submicron VLSI interconnection with high performance and high reliability.

In the following description, a conventional method for fabricating a damascene structure on a substrate is explained with reference to FIGS. 1A to 1D.

First, referring to FIG. 1A, a substrate 100 is provided and a metal interconnect line 110 is fabricated in the substrate 100. An inter-metal dielectric (IMD) layer 120 is formed covering the substrate 100 and the metal interconnect line 110. Referring to the FIG. 1B, the IMD layer 120 is defined by the damascene process to form a dual damascene structure 130 extending through the IMD layer 120 to the metal interconnect line 110.

Then, referring to FIG. 1C, a barrier layer 140 is formed on the sidewalls and the bottom of the dual damascene structure 130 by chemical vapor deposition (CVD) or physical vapor deposition (PVD) process. Afterwards, a metal layer 150 is filled into the dual damascene structure 130 on the barrier layer 140. Finally, referring to FIG. 1D, a chemical mechanical polishing (CMP) process is performed to remove the metal layer 150 and the barrier layer 140 on the IMD layer 120 outside the dual damascene structure 130.

However, after the CMP process, some metal oxide 160 will be generated on the surface of the metal line 150. For example, if the metal is copper, the copper will oxidizes to the copper oxide (Cu₂O). The metal oxide will increase the resistance of the metal line and cause the surface of the metal layer to bulge. Thus, the adhesion between the sealing layer and the metal line will be lessened. Furthermore, the increased resistance of the metal line will generate more heat during operation of the semiconductor device. Moreover, when the adhesion between the sealing layer and the metal line is deteriorated, the electron-migration of the metal line will be degraded, which will negatively influence the performance of the semiconductor devices.

### SUMMARY OF THE INVENTION

The object of the present invention is to provide a method for interconnect structure manufacturing, which can reduce the metal oxide generated on the metal layer after CMP processes is performed. In accordance with the present invention, the invention provides a method for metal reduction in dual damascene process. The method of the present invention uses a reduction gas to reduce metal oxide to metal before deposition of a sealing layer on the metal line. For example, if the metal line is copper, a reduction gas is used to reduce the copper oxide (Cu₂O) to copper (Cu) before depositing the sealing layer on Cu line. A in-situ reduction method can provide a reduction gas such as ammonia (NH₃), hydrogen (H₂), or silane (SiH₄). The flow rate of the reduction gas has a rate between about 20 to 400 sccm, and the deposition pressure is between about 0.01 to 10 torr, and the deposition temperature is between about 300 to 620° C. Moreover, the sealing layer may be the silicon nitride (Si₃N₄), silicon oxynitride (SiON), silicon carbide (SiC), silicon rich oxide (SRO), silicon containing carbon and hydrogen (SiCH), or silicon containing carbon and nitrogen (SiCN).

To achieve the above-mentioned object, the present invention provides a method to fabricate an interconnect structure, comprising the following steps.

First, an inter-metal dielectric layer is formed on a substrate. Then the inter-metal dielectric layer is etched to form a trench. A barrier layer is formed to on the trench. Afterwards, a metal layer is formed to fill into the trench over the barrier layer. Then a chemical mechanical polishing (CMP) process is performed to remove the barrier layer and the metal layer on the inter-metal dielectric layer. After the CMP process, a reduction process is performed by providing a reduction gas to remove the metal oxide generated on the metal layer. Finally, a sealing layer is formed to cover the metal layer.

### BRIEF DESCRIPTION OF THE DRAWINGS

The present invention will become more fully understood from the detailed description given hereinbelow and the accompanying drawings, given by way of illustration only and thus not intended to be limitative of the present invention.

FIGS. 1A-1D are section views illustrating a conventional method of manufacturing an interconnect structure.

FIGS. 2A-2L are section views illustrating a method of manufacturing an interconnect structure according to the embodiment of the present invention.

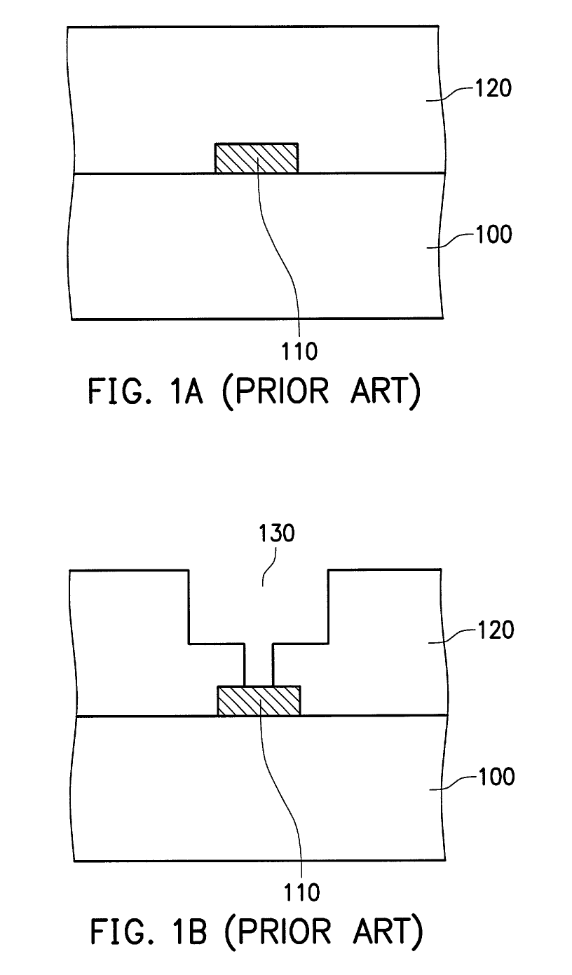

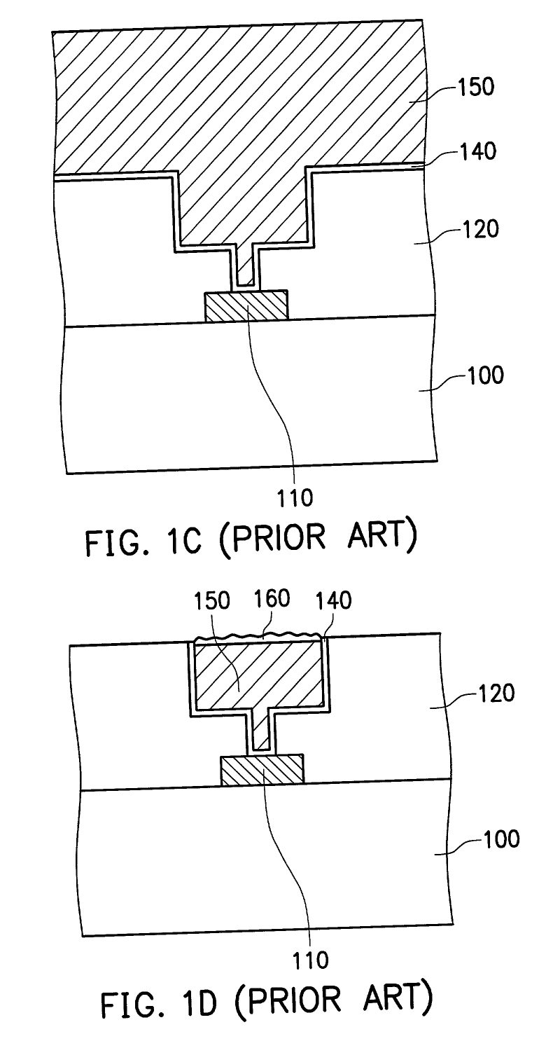

### DETAILED DESCRIPTION OF THE PREFERRED EMBODIMENT

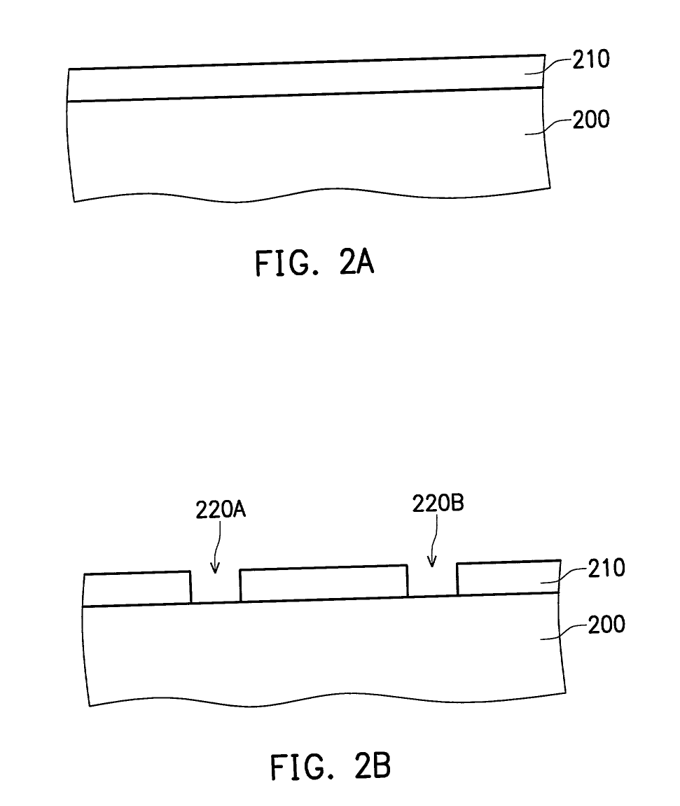

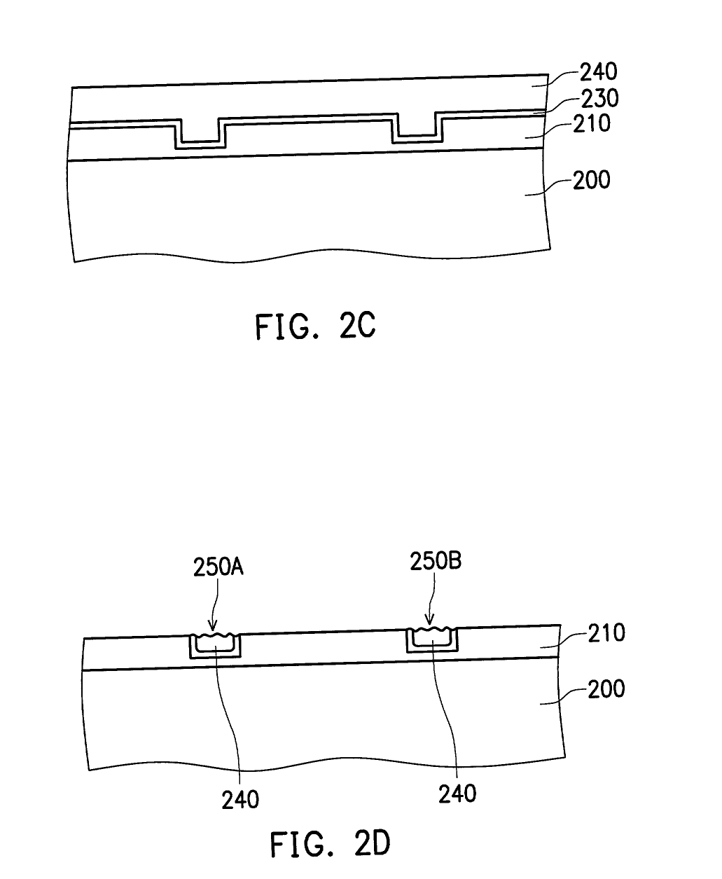

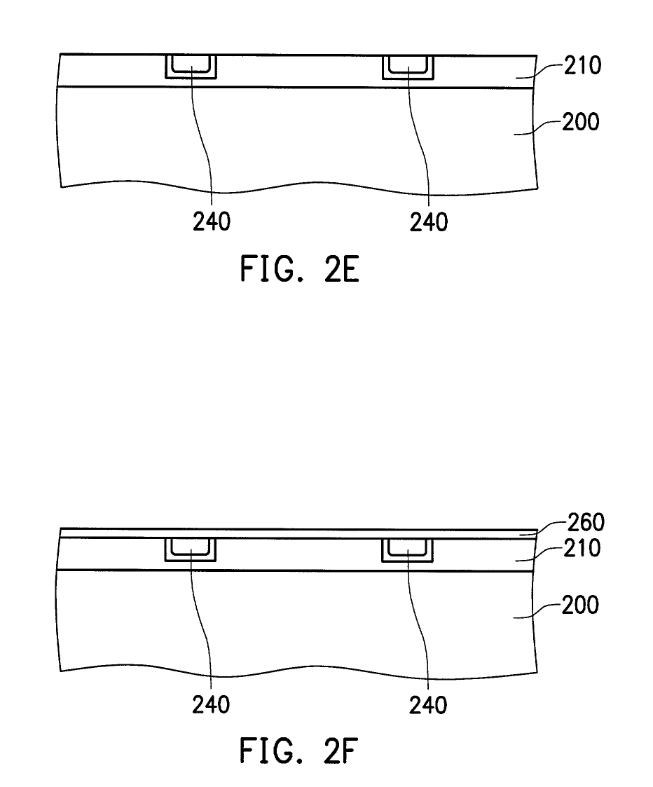

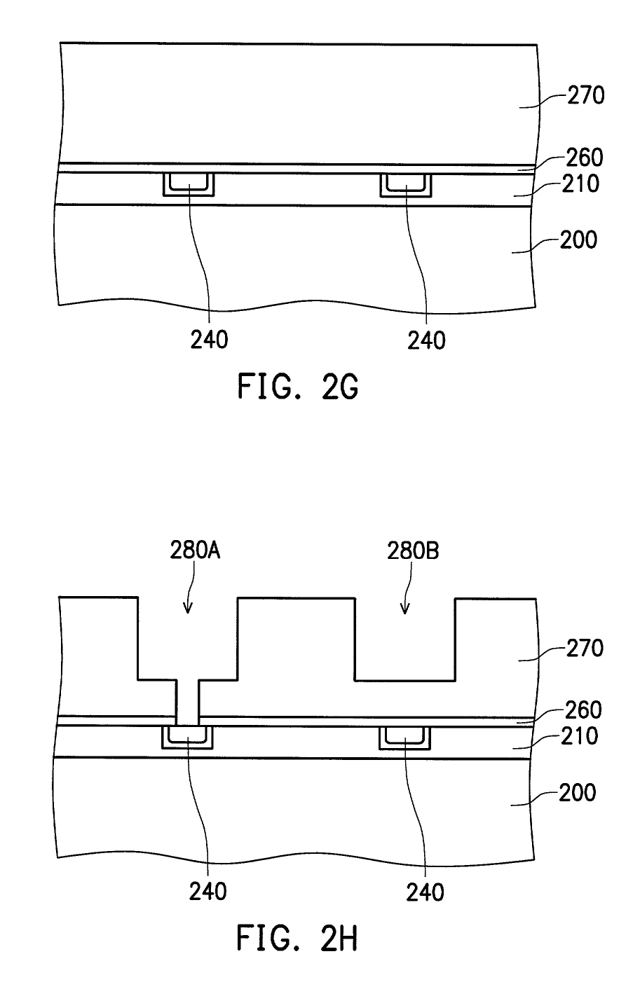

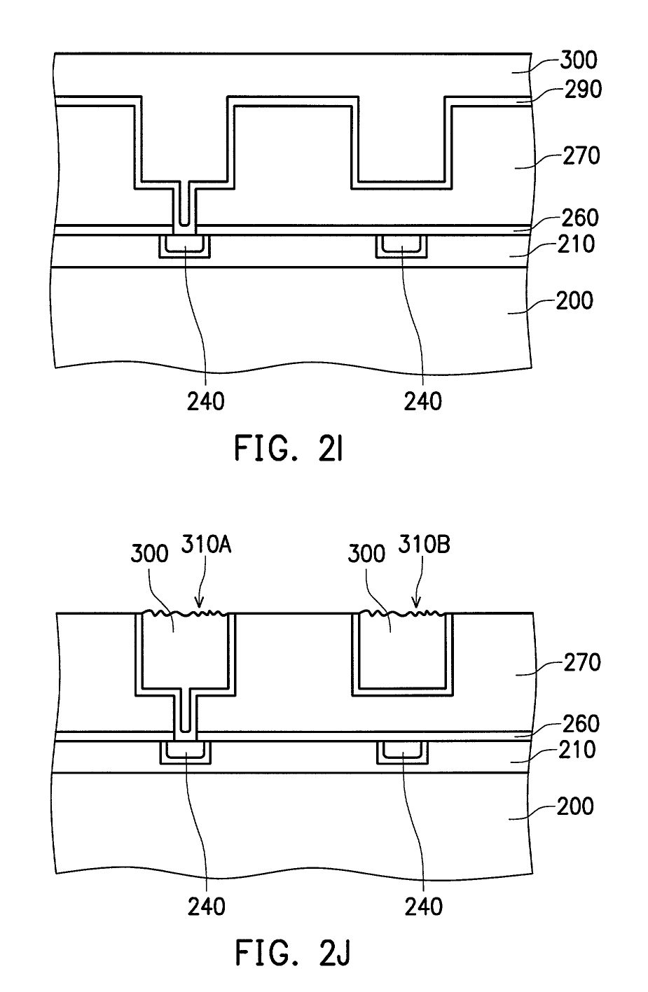

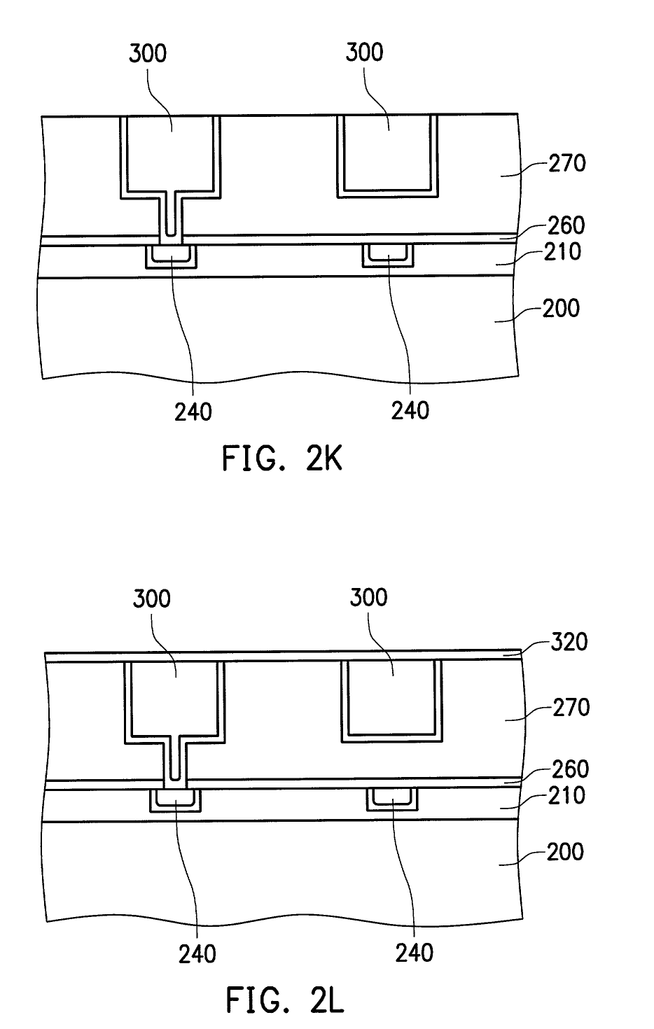

A method to fabricating a dual damascene structure on a substrate is described herein with reference to FIGS. 2A to 2L.

First, referring to FIG. 2A, a substrate 200 is provided for the present embodiment. Then, an inter-metal dielectric (IMD) layer 210 is formed on the substrate. The inter-metal dielectric layer 210 is composed of single layer or multi-layer low k dielectric material, wherein the k is dielectric constant. Next, referring to FIG. 2B, the inter-metal dielectric layer 210 is etched by the lithography technology to form the trenches 220A and 220B. In the present embodiment, the trenches 220A and 220B are formed by the anisotropically etching process, and the depths of the trenches 220A and 220B are between about 2000 to 6000 angstroms.

Referring to FIG. 2C, a barrier layer 230 is formed on the sidewalls and the bottom of the trenches 220A and 220B. Then the metal layer 240 is filled into the trench 220A and 220B on the barrier layer 230. The material of the metal layer 240 may be copper, aluminum, or tungsten, etc. In this embodiment, the metal layer 270 is a copper layer.

Referring to FIG. 2D, a chemical mechanical polishing (CMP) process is performed to remove the metal layer 240 and the barrier layer 230 on the inter-metal dielectric layer 210. However, as shown at the labels 250A and 250B, during the CMP process and after it, the copper oxide (Cu₂O) is generated on the remained metal layer 240 in the trenches 220A and 220B because of the wet. Moreover, the copper oxide (Cu₂O) will cause the surface of the metal layer to bulge. Therefore, the adhesion between the sealing layer 260, which is formed later, and the metal layer 240 is deteriorated. Hence, the reliability of the semiconductor is decreased.

A reduction process is performed to solve this problem. The reduction process provides a reduction gas to the surface of the metal layer 240. Therefore, the Cu₂o is reduced to Cu by free radicals. In the present invention, the reduction gas may be ammonia (NH₃), hydrogen (H₂), or silane (SiH₄). Alternately, the reduction gas may be a mixture of ammonia (NH3) and hydrogen (H₂), or a mixture of silane (SiH₄) and hydrogen (H₂). Preferably, the silane is used as the reduction gas. The reduction process is under the following conditions: a flow rate of the reduction process is between about 20 to 400 sccm; the pressure of the reduction process is between about 0.01 to 10 torr; and the temperature of the reduction process is between about 180 to 620° C.

After the reduction process, as shown in FIG. 2E, the metal oxide (Cu₂O) generated on the surface of the metal layer 240 is removed. Therefore, the surface of the metal layer 240 is planarized.

Afterwards, referring to FIG. 2F, a sealing layer 260 is formed on the inter-metal dielectric layer 210 and the metal layer 240. In the present embodiment, the sealing layer 260 has a thickness between about 100 to 600 angstroms, and the material of the sealing layer 260 may be the silicon nitride (Si₃N₄), silicon oxynitride (SiON), silicon carbide (SiC), silicon rich oxide (SRO), silicon containing carbon and hydrogen (SiCH), or silicon containing carbon and nitrogen (SiCN).

Referring to FIG. 2G, an inter-metal dielectric layer 270 is formed on the sealing layer 260, wherein the inter-metal dielectric layer 270 is composed of single layer or multi-layer low k dielectric materials.

Next, referring to the FIG. 2H, the IMD layer 270 is defined by the damascene process to form a dual damascene structure 280A and a trench 280B. Wherein the dual damascene structure 280A passes through the IMD layer 270 and the sealing layer 260 to the metal line 240, and the trench 280B is in the IMD layer 270.

Then, referring to FIG. 2I, a barrier layer 290 is formed on the IMD layer 270 and the sidewalls and the bottom of the dual damascene structure 280A and the trench 280B by chemical vapor deposition (CVD) or physical vapor deposition (PVD) process. Afterwards, a metal layer 300 is filled into the dual damascene structure 280A and the trench 280B on the barrier layer 290. The material of the metal layer 300 may be copper, aluminum, or tungsten, etc. In this present embodiment, the metal layer 300 is a copper layer.

Afterwards, referring to FIG. 2J, after the metal layer 300 is formed, a chemical mechanical polishing (CMP) process is performed to remove the metal layer 300 and the barrier layer 290 on the IMD layer 270. As mentioned above, during the CMP process and after it, the copper oxide 310A and 310B (Cu₂O) is generated on the remained metal layer 300. Moreover, the copper oxide (Cu₂O) causes the surface of the metal layer to bulge. Therefore, the adhesion between the sealing layer 320, which is formed later, and the metal layer 300 is deteriorated. Hence, the reliability of the semiconductor is decreased.

Thus, a reduction process is performed. The reduction process provides a reduction gas to the surface of the metal layer. Therefore, the Cu₂O reduced to Cu by free radicals. In the present invention, the reduction gas may be ammonia (NH₃), hydrogen (H₂), or silane (SiH₄). Alternately, the reduction gas may be a mixture of ammonia (NH3) or hydrogen (H₂), or a mixture of silane (SiH₄) and hydrogen (H₂). Preferably, the reduction gas is silane (SiH₄). The reduction process is under the following conditions: a flow rate of the reduction process is between about 20 to 400 sccm; the pressure of the reduction process is between about 0.01 to 10 torr; and the temperature of the reduction process is between about 300 to 620° C.

After the reduction process, as shown in FIG. 2K, the metal oxide (Cu₂O) generated on the surface of the metal layer 300 will be removed. Therefore, the surface of the metal layer 300 is planarized.

Afterwards, referring to FIG. 2L, a sealing layer 320 is formed on the inter-metal dielectric layer 270 and the metal layer 300. In the present embodiment, the sealing layer 320 has a thickness between about 100 to 600 angstroms, and the material of the sealing layer 320 may be the silicon nitride (Si₃N₄), silicon oxynitride (SION), silicon carbide (SiC), silicon rich oxide (SRO), silicon containing carbon and hydrogen (SICH), or silicon containing carbon and nitrogen (SiCN).

According to the method of the present invention, the reduction process is performed after a CMP process. Therefore, the generating of the metal oxide after CMP process will be removed. Hence, the present invention reduces the resistance of the Cu line in the dual damascene process. Moreover, the present invention improves the electro-migration of copper and the adhesion between the sealing layer and the metal layer. Furthermore, the method according to the present has the advantages of utilizing conventional tools and being easily integrated into conventional process flows.

The foregoing description of the preferred embodiments of this invention has been presented for purposes of illustration and description. Obvious modifications or variations are possible in light of the above teaching. The embodiments were chosen and described to provide the best illustration of the principles of this invention and its practical application to thereby enable those skilled in the art to utilize the invention in various embodiments and with various modifications as are suited to the particular use contemplated. All such modifications and variations are within the scope of the present invention as determined by the appended claims when interpreted in accordance with the breadth to which they are fairly, legally, and equitably entitled.

What is claimed is:

1. A method to fabricate a interconnect structure, comprising the following steps:
providing a substrate;
forming an inter-metal dielectric layer on the substrate;
forming a trench on the inter-metal dielectric layer by etching the inter-metal dielectric layer;
forming a barrier layer on the inter-metal dielectric layer and the sidewalls and bottom of the trench;
forming a metal layer on the barrier layer to fill into the trench;
performing a chemical mechanical polishing process to planarizate a surface of the metal layer;
performing a reduction process by providing a reduction gas containing silicon to remove the metal oxide generated on the metal layer; and
forming a sealing layer to cover the surface of the metal layer.

2. The method as claimed in claim 1, wherein the material of the metal layer is copper.

3. The method as claimed in claim 2, wherein the reduction gas is silane (SiH₄).

4. The method as claimed in claim 2, wherein the reduction gas is selected from the group consisting of ammonia (NH3), hydrogen (H2), and silane (SiH4).

5. The method as claimed in claim 4, wherein the flow rate of the reduction gas is between about 20 to 400 sccm.

6. The method as claimed in claim 5, wherein the pressure of the reduction process is between about 0.01 to 10 torr.

7. The method as claimed in claim 6, wherein the temperature of the reduction process is between about 300 to 620° C.

8. The method as claimed in claim 7, wherein the material of the sealing layer is selected from the group consisting of silicon nitride (Si₃N₄), silicon oxynitride (SiON), silicon carbide (SiC), silicon rich oxide (SRO), silicon containing carbon and hydrogen (SiCH), and silicon containing carbon and nitrogen (SiCN).

9. A method to fabricate a interconnect structure, comprising the following steps:
providing a substrate having a metal line thereon;
forming a first sealing layer to cover the metal line and the substrate;
forming an inter-metal dielectric layer on the sealing layer;
defining the inter-metal dielectric layer by a damascene process to form a damascene structure extending through the inter-metal dielectric layer to the metal line;
forming a barrier layer on the inter-metal dielectric layer and the sidewalls and bottom of the damascene structure;
forming a metal layer on the barrier layer to fill into the damascene structure;
performing a chemical mechanical polishing process to planarizate a surface of the damascene structure;
performing a reduction process by providing a reduction gas containing silicon to remove the metal oxide generated on the metal layer; and
forming a second sealing layer to cover the metal layer and the inter-metal dielectric layer.

10. The method as claimed in claim 9, wherein the material of the metal layer is copper.

11. The method as claimed in claim 10, wherein the metal oxide is copper oxide.

12. The method as claimed in claim 11, wherein the reduction gas is silane (SiH₄).

13. The method as claimed in claim 11, wherein the reduction gas is selected from the group consisting of ammonia (NH3), hydrogen (H₂), and silane (SiH₄).

14. The method as claimed in claim 13, wherein the flow rate of the reduction gas is between about 20 to 400 sccm.

15. The method as claimed in claim 14, wherein the pressure of the reduction process is between about 0.01 to 10 torr.

16. The method as claimed in claim 15, wherein the temperature of the reduction process is between about 300 to 620° C.

17. The method as claimed in claim 16, wherein the material of the sealing layer is selected from the group consisting of silicon nitride (Si₃N₄), silicon oxynitride (SiON), silicon carbide (SiC), silicon rich oxide (SRO), silicon containing carbon and hydrogen (SiCH), and silicon containing carbon and nitrogen (SiCN).
